(19) United States
(12) Patent Application Publication
(10) Pub. No.: US 2011/0234063 A1
(43) Pub. Date: Sep. 29, 2011

(54) HOUSING OF ELECTRONIC DEVICE AND METHOD FOR MAKING THE SAME

(75) Inventors: BIN LI, Shenzhen City (CN); KAI SHI, Shenzhen City (CN); CHAO-HSUN LIN, Shindian (TW)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/909,949

(22) Filed: Oct. 22, 2010

(30) Foreign Application Priority Data
Mar. 25, 2010 (CN) 201010132897.5

(51) Int. Cl. H05K 5/00; B32B 37/16; B23P 11/00; B23P 19/00; B23K 26/00

(52) U.S. Cl. 312/223.1; 156/242; 29/432; 29/428; 219/121.64

(57) ABSTRACT

A housing of electronic device includes a main plate and a metal peripheral wall, the peripheral wall is fabricated by cold drawn and secured to the periphery of the main plate.

### BACKGROUND

1. Technical Field

The present disclosure relates to a housing of electronic device and a method for making the housing.

2. Description of Related Art

Metal housing of electronic device can be fabricated by punching. However, the punching to the housing may form rough rims at the periphery, and accordingly needs an additional process to remove the rough rims.

Therefore, there is room for improvement within the art.

### BRIEF DESCRIPTION OF THE DRAWINGS

Many aspects of the present housing of electronic device and method for making the same can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the diagrams.

FIG. 1 is a schematic view of a housing of electronic device according to an exemplary embodiment.

FIG. 2 is a cross-sectional schematic view of the housing shown in FIG. 1.

### DETAILED DESCRIPTION

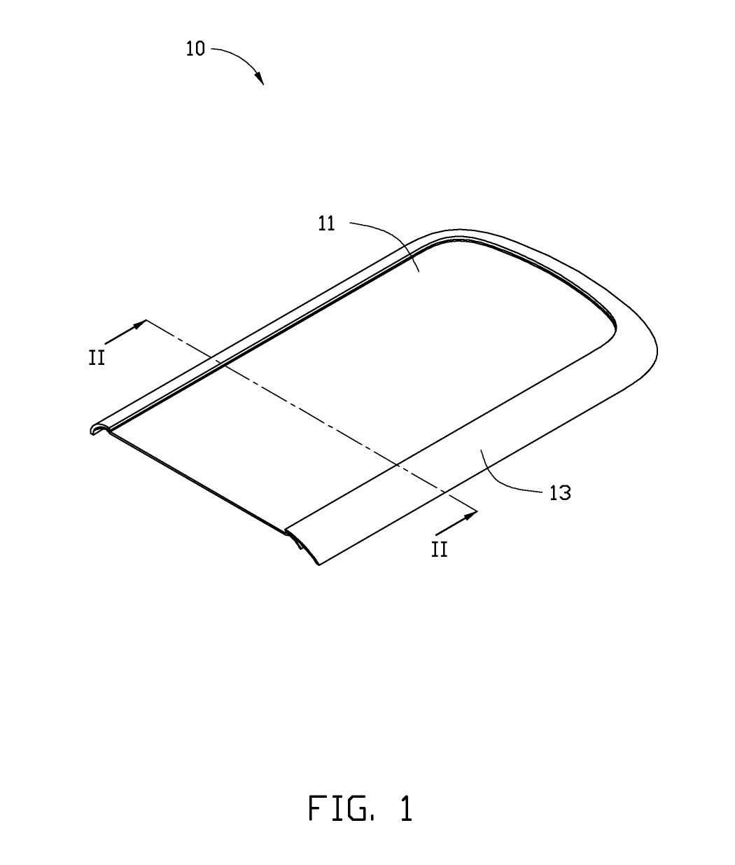

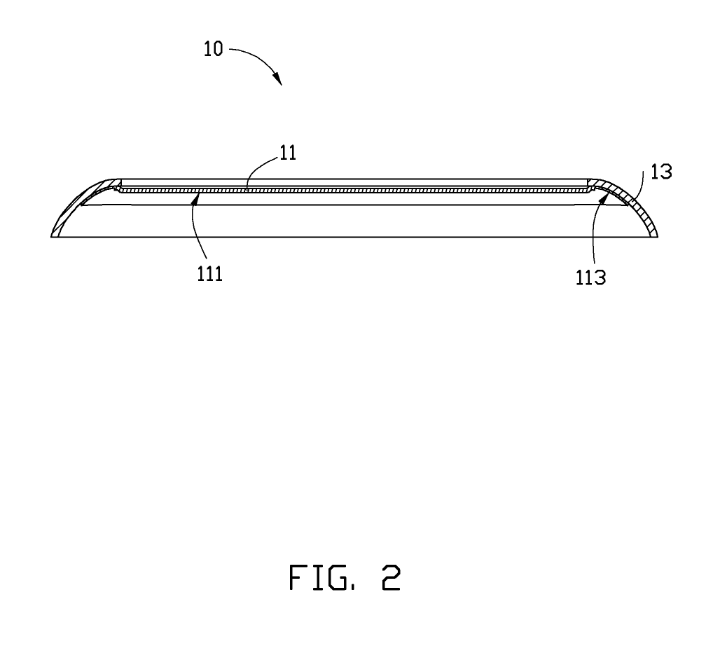

FIGS. 1 and 2 show a housing 10 of an electronic device, such as a mobile phone or a personal digital assistant according to an exemplary embodiment. The housing 10 includes a main plate 11 and a peripheral wall 13. The peripheral wall 13 connects to and surrounds the main plate 11.

The main plate 11 may be made of metal such as stainless steel, stainless steel alloy, aluminum, aluminum alloy, magnesium, magnesium alloy, titanium, titanium alloy etc. The main plate 11 also can be made of one or more impact resistant and wear resistant plastic materials selected from a group including polycarbonate (PC), Polymethyl Methacrylate (PMMA), and Polyamide (PA). The main plate 11 includes a main section 111 with a flange 113 formed on a portion of the periphery of the main section 111. In the present embodiment, the main section 111 is planar and the flange 113 is curved. The thickness of the main section 111 may be about 0.2 millimeter (mm) to about 0.3 mm, and the thickness of the flange 113 may be about 0.15 mm.

The peripheral wall 13 is also curved and connects to the flange 113 of the main plate 11. The peripheral wall 13 may be made of metal such as stainless steel, stainless steel alloy, aluminum, aluminum alloy. The peripheral wall 13 can be cold drawn. In the present embodiment, the thickness of the peripheral wall 13 may be about 0.5 mm.

The peripheral wall 13 can be connected to the main plate 11 by laser welding. During welding, the peripheral wall 13 is aligned with and abuts the flange 113 of the main plate 11. The adjoining area of the peripheral wall 13 and the flange 113 is heated and melted by a laser and cooled to secure the peripheral wall 13 to the flange 113. In other embodiments, the peripheral wall 13 can be curved in such a way as to be able to hook to the main plate 11.

In other embodiments, to save on material when strength is less important the flange 113 of the main plate 11 can be omitted, and the peripheral wall 13 directly connected to the periphery of the main section 111.

A method to make the housing 10 includes following steps.

The main plate 11 is provided and can be fabricated by, for example, punching a sheet metal or injection molding a plastic material. The main plate 11 includes the main section 111 and the flange 113.

A metal material is provided and processed by cold drawing to form the peripheral wall 13.

The peripheral wall 13 is positioned on the flange 113 of the main plate 11, and a portion of the peripheral wall 13 substantially abuts the flange 113. The adjoining area of the peripheral wall 13 and the flange 113 is heated and melted by a laser and then cooled to secure the peripheral wall 13 with the flange 113. Therefore, the housing 10 can be made.

It is to be understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A housing of electronic device, comprising:
a main plate;
a metal peripheral wall; wherein:
the peripheral wall is cold drawn and secured to the periphery of the main plate.

2. The housing of electronic device as claimed in claim 1, wherein the main plate is punched sheet metal.

3. The housing of electronic device as claimed in claim 2, wherein the metal includes stainless steel, stainless steel alloy, aluminum, aluminum alloy, magnesium, magnesium alloy, titanium, titanium alloy.

4. The housing of electronic device as claimed in claim 1, wherein the main plate includes a main section with a flange formed on a portion of the periphery of the main section, the peripheral wall is secured with the flange.

5. The housing of electronic device as claimed in claim 4, wherein the main section has a thickness in the range of about 0.2 mm (millimeter) to about 0.3 mm, the edging having a thickness of about 0.15 mm.

6. The housing of electronic device as claimed in claim 1, wherein the peripheral wall can be made of metal including stainless steel, stainless steel alloy, aluminum, aluminum alloy.

7. The housing of electronic device as claimed in claim 1, wherein the peripheral wall is secured to the main plate by laser welding.

8. The housing of electronic device as claimed in claim 1, wherein the main plate is formed by injection molding a plastic material.

9. The housing of electronic device as claimed in claim 8, wherein the plastic material is selected from a group including polycarbonate (PC), Polymethyl Methacrylate (PMMA), and Polyamide (PA).

10. A method for making a housing of electronic device, comprising:
providing a main plate;
providing a metal material, cold drawing the metal material to form a peripheral wall;
securing the peripheral wall to the periphery of the main plate to form the housing.

11. The method for making the housing of electronic device as claimed in claim 10, wherein the main plate is formed by punching a metal material.

12. The method for making the housing of electronic device as claimed in claim 10, wherein the main plate is formed by injection molding a plastic material.

13. The method for making the housing of electronic device as claimed in claim 10, wherein the peripheral wall is secured to the main plate by laser welding.

14. The method for making the housing of electronic device as claimed in claim 10, wherein main plate includes a main section with a flange integrally formed on a portion of the periphery of the main section, the peripheral wall is secured to the flange.
